(19) United States
(12) Patent Application Publication
(10) Pub. No.: US 2014/0184212 A1
(43) Pub. Date: Jul. 3, 2014

(54) CURRENT DETECTION CIRCUIT MODULE

(71) Applicants: Kazuhiko Yamaguchi, Tochigi (JP); Takuya Yamamura, Tochigi (JP)

(72) Inventors: Kazuhiko Yamaguchi, Tochigi (JP); Takuya Yamamura, Tochigi (JP)

(73) Assignee: HONDA MOTOR CO., LTD., Tokyo (JP)

(21) Appl. No.: 14/237,263

(22) PCT Filed: Apr. 26, 2012
(86) PCT No.: PCT/JP2012/061222

§ 371 Date: Feb. 5, 2014

(30) Foreign Application Priority Data
Aug. 31, 2011 (JP) 2011-188301

(51) Int. Cl. G01R 19/00

(52) U.S. Cl. CPC G01R 19/0092
USPC 324/244

(57) ABSTRACT

A current detection circuit module can correct the sensitivity of current detection before a finished product is fabricated, with high impact resistance. The current detection circuit module has a circuit board on which a control IC is mounted. A magnetic core has a gap at a part thereof. A magnetic detection element is disposed in the gap. A detection circuit outputs a detection signal of a current value flowing to the control IC in accordance with the output of the magnetic detection element. A pass portion is provided to the control circuit board. The magnetic core is mounted on the control circuit board to surround the bus bar. The magnetic detection element is mounted on the control circuit board and is located in the gap.

### TECHNICAL FIELD

The present invention relates to a current detection circuit module for detecting current flowing in a current conducting wire.

### BACKGROUND ART

A three-phase inverter circuit module for controlling a driving motor or a generator (electrical power generator) is mounted in an electrically powered vehicle. In the following description, these devices would be referred to as rotating electrical machines when it is unnecessary to discriminate them from each other.

In general, a three-phase inverter circuit module 80 has a three-phase inverter circuit 82 as a power module for driving a three-phase rotating electrical machine 81, a smoothing capacitor 84 for stabilizing voltage supplied from a main battery 83 to the three-phase inverter circuit 82, a three-phase inverter control circuit unit 85 for controlling the three-phase inverter circuit 82, and a current detection circuit module 86 for detecting current flowing in the three-phase rotating electrical machine and outputting the detected current to the three-phase inverter control circuit unit 85 as shown in FIG. 13.

The three-phase inverter circuit 82 is a circuit that is configured so that an up-and-down arm is constructed by connecting switching elements 87 such as IGBTs or the like in series and up-and-down arms corresponding to three phases are connected to one another in parallel with respect to a main battery 83, and outputs AC power through bus bars 88 extending from in-series connection points of the switching elements 87. The three-phase rotating electrical machine 81 is provided with a phase terminal (not shown) for each of U-phase, V-phase and W-phase, and the bus bars 88 as current conducting wires extending from the three-phase inverter circuit 82 are connected to the respective phase terminals, whereby AC power is supplied to the three-phase rotating electrical machine 81.

The detection current circuit module 86 is constructed by modularizing a magnetic detection element 93 as a current sensor (see FIGS. 14(A), 14(B)) and various kinds of circuits, and it is provided for each of U-phase, V-phase and W-phase of the three-phase rotating electrical machine to detect the current of each phase and output the detected current to the three-phase inverter control circuit unit 85.

The three-phase inverter control circuit unit 85 is configured to have a control circuit 90 for generating a PWM signal for driving the three-phase rotating electrical machine 81 on the basis of the current value of each phase and an angle, an angular velocity, etc. detected by an angular velocity detection sensor (not shown), and a power module driving circuit 91 for driving the three-phase inverter circuit 82 according to the PWM signal.

As shown in FIG. 14(A), the current detection circuit module 86 generally comprises an annular magnetic core 92 which surrounds a bus bar 88 and has a gap 97 at a part thereof, a magnetic detection element 93 for detecting magnetic flux density in the gap, a differential amplifier 94 for rectifying an electrical output of the magnetic detection element, a constant current source 95 for supplying driving current to the magnetic detection element 93, and a correction circuit 96 for performing current detection sensitivity correction on both or one of the constant current source 95 and the differential amplifier 94. Furthermore, there is also known a current detection circuit module 186 that feeds back the output of the differential amplifier 94 to make current flow through a correction coil secured to the magnetic core 92, thereby correcting linearity and hysteresis as shown in FIG. 14(B).

Specifically, there is broadly used packaged IC containing a hall element, a magnetoresistance (MR) element (containing GMR, TMR or the like), a signal amplifier (amplifier), etc.

There have been hitherto proposed various kinds of three-phase inverter circuit modules 80 which are configured to have an integrated structure of the current detection circuit module 86 and the three-phase inverter control circuit unit 85 to reduce the number of parts to be mounted at the connection portion between the current detection circuit module 86 and the three-phase inverter control circuit unit 85 and also enhance noise resistance performance (for example, see Patent Documents 1 to 3).

Patent Document 1 discloses a structure that the magnetic core 92, the magnetic detection element 93 and the differential amplifier 94 are mounted on a board (not shown) on which the control circuit 90 of the three-phase inverter control circuit unit 85 is mounted, and the bus bar is set to extend in parallel to the board.

Furthermore, Patent Document 2 discloses a structure that the magnetic detection element 93 and the differential amplifier 94 are mounted on a board on which the control circuit is mounted, the magnetic core is divided into a board side core provided to the board and bus bar side core provided to the bus bar so that the board side core provided to the board and the bus bar side core provided to the bus bar are disposed to be proximate to each other.

Patent Document 3 discloses a structure that the magnetic detection element 93 and the differential amplifier 94 are mounted on a board on which the control circuit is mounted, the magnetic core is fixed by a fixing jig and the bus bar is inserted through the magnetic core.

### PRIOR ART DOCUMENT

### Patent Document

Patent Document 1: Patent No. 3,734,122
Patent Document 2: JP-A-2005-300170
Patent Document 3: JP-A-2007-147565

### SUMMARY OF THE INVENTION

### Problem to be solved by the Invention

However, in the structures of the Patent Document 1 and the Patent Document 2, when the current detection sensitivity of the magnetic detection element is corrected, the correction cannot be performed until the magnetic core and the magnetic detection element has been assembled with each other because they are configured as separate structures and thus the current detection itself cannot be performed until the assembly is completed. Therefore, the current detection sensitivity is corrected after the module of the three-phase inverter circuit module 80 is fabricated. Accordingly, there are many cases that the correction of the current detection sensitivity is insufficient, and also there is a problem that a work-in-process loss increases when a disadvantage occurs at the final stage of the fabrication.

On the other hand, according to the structure of the Patent Document 3, by using a fixing jig the magnetic core is fixed at the outside of the board on which the control circuit is mounted. Therefore, the current detection sensitivity can be corrected with the board being set alone by passing a conductor for correcting the current detection sensitivity through the magnetic core without passing the bus bar through the magnetic core.

However, the magnetic core is provided at the outside of the board, and thus the structure thereof is weak to a mechanical impact. Particularly, since an electrically-operated vehicle causes a large impact due to the operation thereof, and thus strong resistance to the mechanical impact under operation is required. Therefore, there is a problem that the structure of the Patent Document 3 is unusable in the electrically-operated vehicle.

As described above, the conventional structure in which the board having the control circuit mounted thereon and the current detection circuit module 86 are integrated with each other has the foregoing problem. Therefore, the board and the current detection circuit module 86 have been still manufactured as separate bodies to perform optimum-value manufacturing and reduce the work-in-process loss under present circumstances.

The present invention has been implemented in view of the foregoing situation, and has an object to provide a current detection circuit module that can correct current detection sensitivity before a completed product is fabricated and also can perform high resistance performance to mechanical impact.

### Means of Solving the Problem

This specification contains the whole content of Japanese Patent Application No. 2001-188301 filed on Aug. 31, 2011.

In order to attain the above object, according to the present invention, a current detection circuit module has a control circuit board on which a control circuit for controlling a power module is mounted, a magnetic core that surrounds a current conducting wire extending from the power module and has a gap at a part thereof, a magnetic detection element disposed in the gap, and a detection circuit for outputting a detection signal of a current value flowing in the current conducting wire to the control circuit in accordance with an output of the magnetic detection element, the detection circuit being mounted on the control circuit board, wherein the control circuit board is provided with a pass portion based on a cut-out or through-hole to dispose the current conducting wire vertically to the surface of the board, the magnetic core is provided to the control circuit board so as to surround the current conducting wire through the pass portion, and the magnetic detection element is provided to the control circuit board so as to be located in the gap of the magnetic core.

According to the present invention, the magnetic core and the magnetic detection element are mounted together on the control circuit board on which the control circuit and the detection circuit are mounted, and the pass portion in which the current conducting wire as a detection target is passed is provided to the control circuit board. Therefore, in place of the current conducting wire of the power module, a conductor in which current for correcting sensitivity is made to flow is passed through the pass portion, whereby the sensitivity of the magnetic detection element can be corrected by using only the control circuit board without fabricating the power module. Accordingly, the present invention can simplify the shipping inspection step, suppress the work-in-process loss and contribute to flexible production.

Furthermore, the magnetic core is mounted on the control circuit board, whereby the resistance to the mechanical impact can be enhanced.

Furthermore, according to the present invention, in the above current detection circuit module, the magnetic core is disposed so as to be fit within the surface of the control circuit board.

According to the present invention, the magnetic core is fitted within the surface of the control circuit board, so that the resistance to mechanical impact can be maximized while the contact area between the magnetic core and the control circuit board is maximum.

Still furthermore, according to the present invention, in the above current detection circuit module, the magnetic core and the magnetic detection element are provided for each of plural current conducting wires extending from the power module, and a correction circuit for correcting an output of each of the magnetic detection elements and outputting the corrected output to the detection circuit or correcting a detection signal of each magnetic detection element output from the detection circuit and outputting the corrected detection signal is mounted on the control circuit board.

According to the present invention, correction circuits for respectively correcting the plural magnetic detection elements are integrated into one correction circuit, and thus the number of parts to be mounted can be greatly reduced.

Still furthermore, according to the present invention, in the above current detection circuit module, the magnetic core is disposed on the surface of the control circuit board.

According to the present invention, both the surfaces of the control circuit board can be efficiently used, and the degree of the layout of the mount surface of the control circuit can be enhanced.

Still furthermore, according to the present invention, in the current detection circuit module, the magnetic core is provided so as to penetrate through the control circuit board to the obverse and reverse surfaces of the control circuit board.

According to the present invention, the protrusion of the magnetic core from the surface of the control circuit board can be suppressed, and the rigidity of the control circuit board can be enhanced by the magnetic core.

Still furthermore, according to the present invention, in the above current detection circuit module, the magnetic core is divided into a first magnetic core and a second magnetic core that are configured to be substantially U-shaped in plan view and arranged so as to sandwich the control circuit board from upper and lower sides so that open end portions of the first and second magnetic cores are overlapped with each other in plan view, and the magnetic detection element is provided between the open end portions of the first and second magnetic cores.

According to the present invention, both the surfaces of the control circuit board can be efficiently used, and the degree of the layout of the mount surface of the control circuit can be enhanced.

Still furthermore, according to the present invention, in the above current detection circuit module, the magnetic core is electrically grounded to the control circuit board.

According to the present invention, the capacitance between the magnetic core and the control circuit board and the capacitance between the magnetic core and the magnetic detection element can be reduced, and the effect of electrostatic induction noise caused by a voltage applied to the current conducting wire can be reduced.

Still furthermore, according to the present invention, in the above current detection circuit module, the correction circuit comprises an amplifier for amplifying an output of each magnetic detection element and outputting the amplified output to the detection circuit, a variable resistor for enabling digital setting of a resistance value for adjusting the gain of the amplifier every magnetic detection element, a DC voltage variable power supply that can digitally set a DC voltage for adjusting offset of an output of each magnetic detection element, and control means for setting adjustment values of the gain and the offset to the variable resistor and the DC voltage variable power supply every magnetic detection element.

According to the present invention, the correction can be performed in a digital style. Therefore, as compared with the analog style correction of changing the resistance value with a trimming resistor or the like, accurate setting and resetting can be performed. Furthermore, the amplifier, the variable resistor, the DC voltage variable power supply and the control means are constructed as a monolithic device and integrated as a single circuit. Therefore, the number of parts and the cost can be reduced while the digital style correction is performed.

The gain of the amplifier may be corrected by other means of performing the correction by changing a current amount flowing in the magnetic detection element, and correction circuits for correcting the gain of the amplifier in accordance with the sensitivity of the magnetic detection elements may be constructed as a monolithic device and integrated into a single circuit.

Still furthermore, according to the present invention, in the above current detection circuit module, the control circuit board has a constant current source for supplying constant current to each of the magnetic detection element, and a differential amplifier which receives an output of each of the magnetic detection element, amplifies the output and outputs the amplified output to the correction circuit.

According to the present invention, the constant current source and the differential amplifier which are required every magnetic detection element are integrated, and the number of parts to be mounted and the cost can be reduced.

### Effect of the Invention

According to the present invention, the magnetic core and the magnetic detection element are mounted together on the control circuit board on which the control circuit and the detection circuit are mounted, and the pas portion through which the current conducting wire as the detection target is passed is provided to the control circuit board. Therefore, in place of the current conducting wire as the detection target, a conductor through which current for correcting sensitivity is made to flow is passed through the pass portion, whereby the sensitivity of the magnetic detection element can be corrected with the control circuit board set alone without fabricating the power module. Accordingly, the shipping inspection step can be simplified, and the present invention can suppress the work-in-process loss and contribute to the flexible product.

Furthermore, the magnetic core is mounted on the control circuit board, and thus the resistance to the mechanical impact can be enhanced.

In the present invention, the magnetic core is disposed so as to be fit within the surface of the control circuit board, whereby the contact area between the magnetic core and the control circuit board is maximum and the resistance to the mechanical impact can be enhanced to the maximum level.

Furthermore, in the present invention, the magnetic core and the magnetic detection element are provided for each of the plural current conducting wires extending from the power module, and the correction circuit for correcting the output of each of the magnetic detection element and outputting the corrected output to the detection circuit or correcting the detection signal of each magnetic detection element output from the detection circuit and outputting the corrected detection signal is mounted on the control circuit board. Therefore, correction circuits for correcting the respective plural magnetic detection elements are integrated into one circuit, and the number of parts to be mounted can be greatly reduced.

Still furthermore, the magnetic core is disposed on the surface of the control circuit board, and both the surfaces of the control circuit board can be efficiently used. In addition, the degree of freedom of the layout on the mount face of the control circuit can be enhanced.

Furthermore, in the present invention, the magnetic core is provided so as to penetrate through the control circuit board to both the obverse and reverse surfaces of the control circuit board, whereby the protrusion of the magnetic core from the surface of the control circuit board can be suppressed, and the rigidity of the control circuit board can be enhanced by the magnetic core.

Still furthermore, the magnetic core is divided into the first and second magnetic cores which are designed to be substantially U-shaped in plan view, the first and second magnetic cores are arranged so as to sandwich the control circuit board from the upper and lower sides so that the open end portions of the first and second magnetic cores are overlapped with each other in plan view, and the magnetic detection element is provided between the open end portions of the first and second magnetic cores. Accordingly, both the surfaces of the control circuit board can be efficiently used, and the degree of freedom of the layout on the mount face of the control circuit can be enhanced.

In the present invention, the magnetic core is electrically grounded to the control circuit board, whereby the capacitance between the magnetic core and the control circuit board and the capacitance between the magnetic core and the magnetic detection element can be reduced, and the effect of the electrostatic induction noise caused by the voltage applied to the current conducting wire can be reduced.

### BRIEF DESCRIPTION OF THE DRAWINGS

FIG. 1 is a diagram showing the structure of a three-phase inverter circuit module according to an embodiment of the present invention.

FIG. 2 is an enlarged view of the neighborhood of the current detection circuit module in FIG. 1, wherein (A) is a side view and (B) is a plan view.

FIG. 3 is a diagram showing the structure of the current detection circuit module when current detection sensitivity is corrected.

FIG. 4 is a circuit diagram showing the structures of a magnetic detection element and a current sensor circuit.

FIG. 5 is a circuit diagram showing the construction of a correction circuit.

FIG. 6 is a diagram showing a modification of a mounting mode of a magnetic core on a control circuit board.

FIG. 7 is a diagram showing a modification of the mounting mode of the magnetic core on the control circuit board.

FIG. 8 is a diagram showing a modification of the mounting mode of the magnetic core on the control circuit board.

FIG. 9 is a diagram showing a modification of the mounting mode of the magnetic core on the control circuit board.

FIG. 10 is a diagram showing a modification of a pass portion of the control circuit board.

FIG. 11 is a diagram showing a modification of a mounting mode of a magnetic detection element on the control circuit board.

FIG. 12 is a circuit diagram showing a modification of a current detection circuit module.

FIG. 13 is a diagram showing an example of a conventional three-phase inverter circuit module.

FIG. 14 is a diagram showing an example of a conventional current detection circuit module.

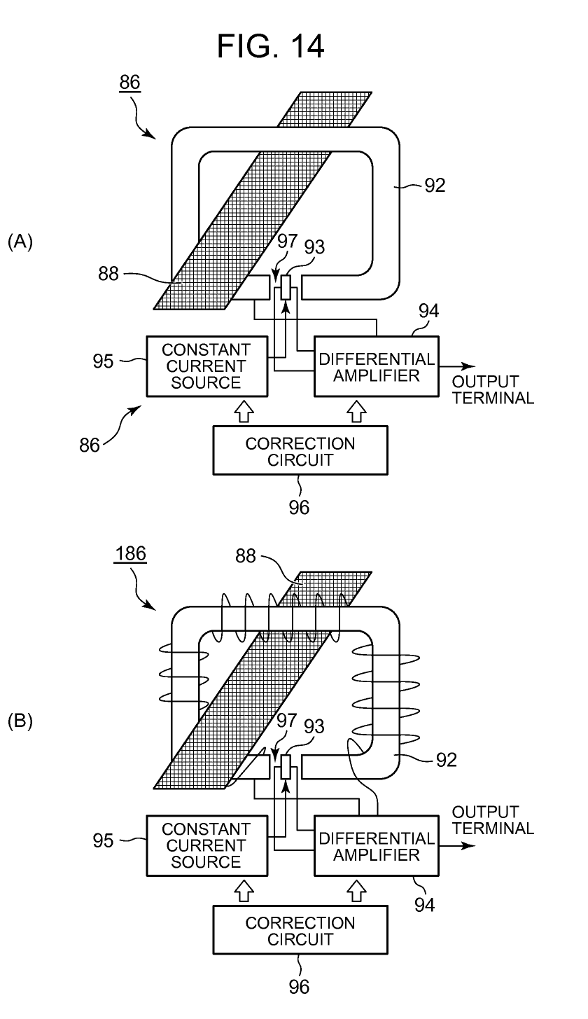

### BEST MODE FOR CARRYING OUT THE INVENTION

An embodiment according to the present invention will be described hereunder with reference to the drawings.

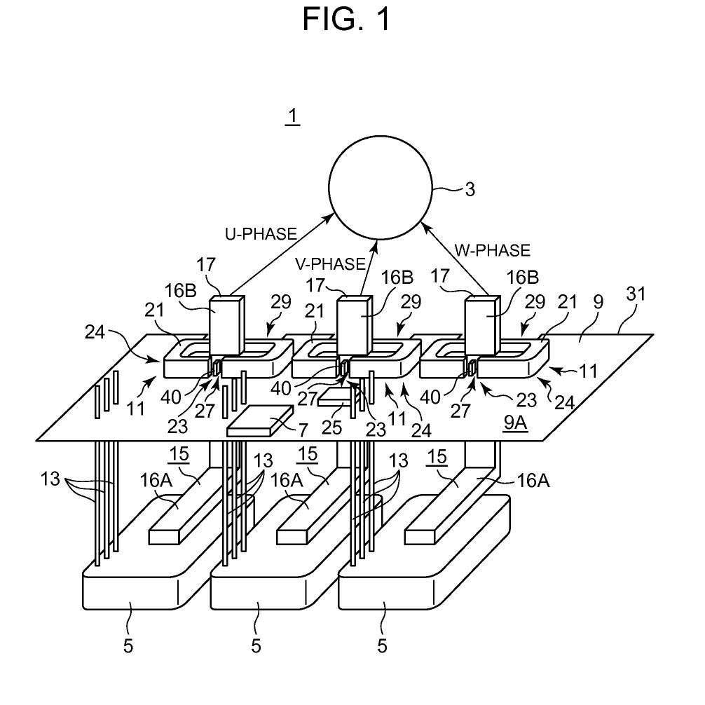

FIG. 1 is a diagram showing the structure of a three-phase inverter circuit module 1 according to the embodiment.

The three-phase inverter circuit module 1 is mounted in an electrically powered vehicle such as an electric car or the like, and controls a driving motor or a generator (these devices will be hereunder referred to as “three-phase rotating electric machines” and represented by reference numeral 3). As shown in FIG. 1, the three-phase inverter circuit module 1 has power modules 5, a control IC 7, a control circuit board 9 on which the control IC 7 is mounted, and current detection circuit modules 11 mounted on the control circuit board 9 together with the control IC 7.

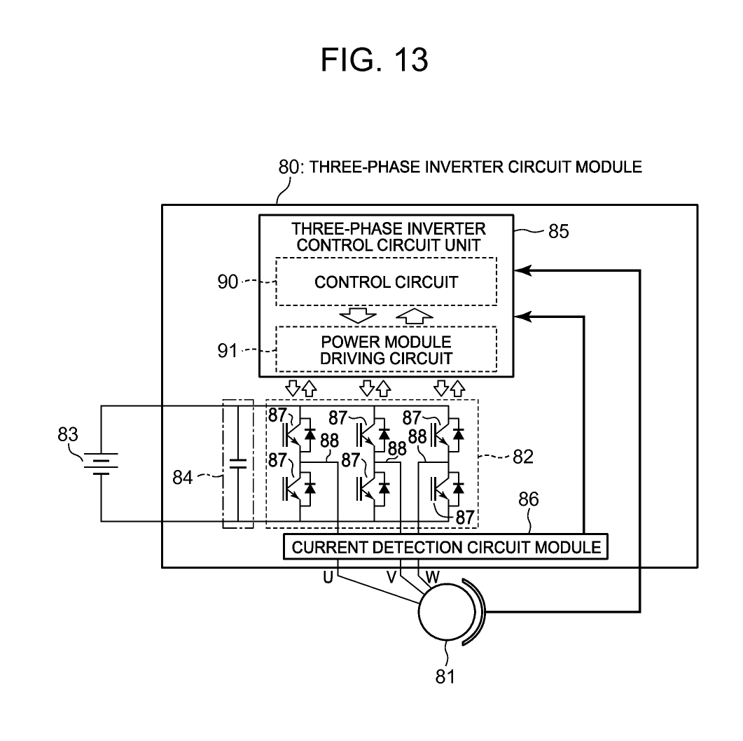

The power module 5 is obtained by modularizing, as a package, a pair of switching elements (see FIG. 13) constituting an up-and-down arm of each of the U-phase, V-phase and W-phase of the three-phase inverter circuit, for example, and it is provided to each of the three phases. However, the structure of the power module 5 is not limited to a structure that a pair of switching elements constituting the up-and-down arm are modularized into one body, but may be a structure that the switching elements corresponding to the upper arms are modularized while the switching elements corresponding to the lower arms are modularized, or a structure that the switching elements corresponding all the up-and-down arms of the U-phase, V-phase and W-phase are modularized into one body.

The control IC 7 is a circuit for controlling each of the power modules 5, and designed as one-chip IC constituting the conventional three-phase inverter control circuit unit 85 described with reference to FIG. 1. The control IC 7 is mounted on the control circuit board 9.

The control circuit board 9 is a print board on which various kinds of wires are printed, and it is disposed so as to cover the upper sides of the respective modules 5 arranged side by side. Power module control terminals 13 extend upwards vertically, penetrate through the control circuit board 9 and connect to wires formed on the control circuit board 9, whereby the control IC 7 and the power modules 5 are electrically connected to each other.

A bus bar 15 is connected to the upper surface of each power module 5. The bus bar 15 is constructed by vertically erecting a conductor portion 16B from a terminal table 16A to which various kinds of equipment such as the power module 5, etc. can be connected. That is, when the power module 5 is secured to the terminal table 16A of the bus bar 15, the conductor portion 16B of the bus bar 15 extends upwards vertically, and the upper end portion 17 of the conductor portion 16B is connected to a phase terminal (not shown) of the three-phase rotating electric machine 3. The bus bar 15 may be integrated with the power module 5, or the upper end portion 17 of the bus bar 15 may be provided with the terminal table.

The current detection module 11 is a device which is provided every bus bar 15, detects current flowing in the bus bar 15 and outputs the detected current to the control IC 7. The control IC 7 generates a PWM signal for driving the three-phase rotating electric machine on the basis of the current values of the respective phases and the degree, angular velocity, etc. which are detected by an angular velocity detection sensor (not shown), and drives the respective power module 5 according to the PWM signal.

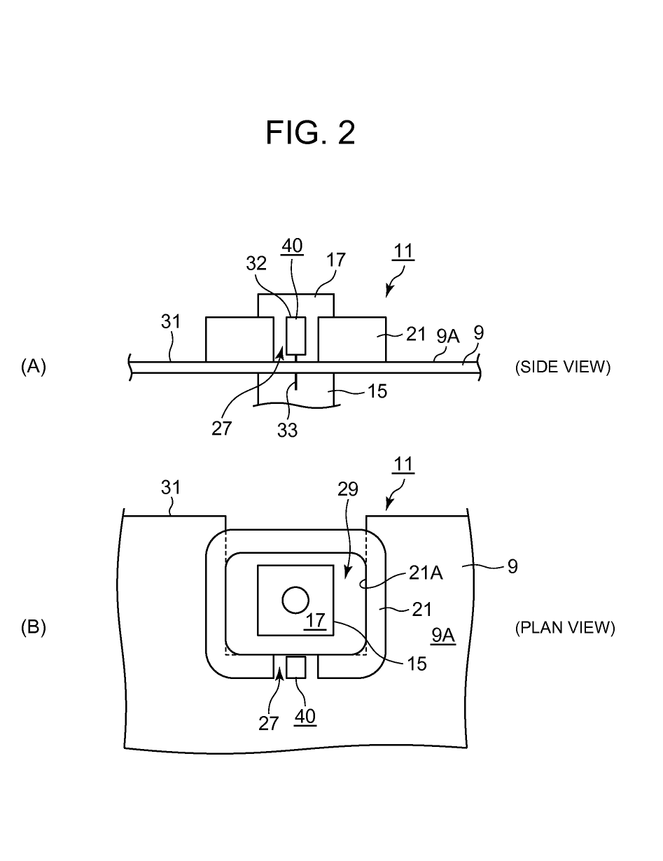

FIG. 2 is an enlarged view of the neighborhood of the current detection circuit module 11 in FIG. 1, wherein FIG. 2(A) is a side view and FIG. 2(B) is a plan view.

As shown in FIGS. 1 and 2, the current detection circuit module 11 has a magnetic core 21, a magnetic detection element 40, and a current sensor circuit 25 (not shown in FIG. 2) which is shared by the respective magnetic detection elements 40.

The magnetic core 21 is a member constituting a substantially annular member which surrounds the bus bar 15 and has a gap 27 at a part thereof, and generates a magnetic flux density corresponding to current flowing in the bus bar 15. The magnetic core 21 of this embodiment comprises a member which is configured to have a rectangular frame shape (so-called rectangular ring shape) in section so that one side of the rectangular frame shape is partially opened as a gap and have a predetermined height. The thus-constructed magnetic core 21 is mounted on a mount face 9A (see FIG. 2(B)) of the control circuit board 9.

Describing in more detail, as shown in FIG. 2(B), the mount face 9A of the control circuit board 9 is provided with a pass portion 29 through which the bus bar 15 extending upwards vertically are passed between the obverse and reverse sides. The pass portion 29 is formed by cutting out a part of the edge portion 31 of the control circuit board 9, and the magnetic core 21 is mounted on the control circuit board 9 so as to surround the bus bar 15 passing through the pass portion 29.

An opening through which the bus bar 15 is inserted may be formed in the plane of the control circuit board 9 to form the pass portion 29 in place of cutting out the edge portion 31 of the control circuit board 9 to form the pass portion 29.

When the magnetic core 21 is mounted on the control circuit board 9, the magnetic core 21 is coated with resin material, and then fixed so that the inner peripheral surface 21A of the substantially annular magnetic core 21 is vertical to the mount face 9A of the control circuit board 9. For example, a screwing method, an adhesion method using adhesive agent or a fixing method of pressing the magnetic core 21 to the control circuit board 9 by using a press mechanism such as a spring or the like may be used as a method of fixing the magnetic core 21 to the control circuit board 9.

The magnetic core 21 may be electrically grounded to the control circuit board 9 when the magnetic core 21 is mounted on the control circuit board 9, whereby the capacitance between the magnetic core 21 and the control circuit board 9 and the capacitance between the magnetic core 21 and the magnetic detection element 40 can be eliminated. Accordingly, an effect of electrostatic induction noise caused by a voltage applied to the bus bar 15 (current conductor) can be reduced. Adhesion based on conductive adhesion agent, a spring, a gasket or the like, direct brazing (soldering or the like) onto the control circuit board 9 or the like may be used as a fixing method of electrically grounding the magnetic core 21 to the control circuit board 9.

The magnetic core 21 is mounted in such a posture that the gap 27 is located within the mount face 9A of the control circuit board 9, and the magnetic detection element 40 is mounted in the gap 27.

The magnetic detection element 40 is a hall element, a magnetoresistance (MR) element (containing GMR, TMR, etc.) or the like, and the hall element is used in this embodiment. A hall IC having a lock-in amplification function or an off-set correction circuit may be used in place of the hall element. Furthermore, as shown in FIG. 2(A), the magnetic detection element 40 has an element portion and a terminal portion 33 extending vertically downwards from the bottom portion of the element portion 32.

An insertion hole (not shown) in which the terminal portion 33 is inserted is formed substantially at the center position of the gap 27 in the mount face 9A of the control circuit board 9. By inserting the terminal portion 33 in the insertion hole, the element portion 32 is vertically erected from the mount face 9A of the control circuit board 9 substantially at the center position in the gap 27, whereby magnetic flux occurring in the gap 27 can be accurately and evenly detected by the element portion 32 and thus accurate current measurement can be performed.

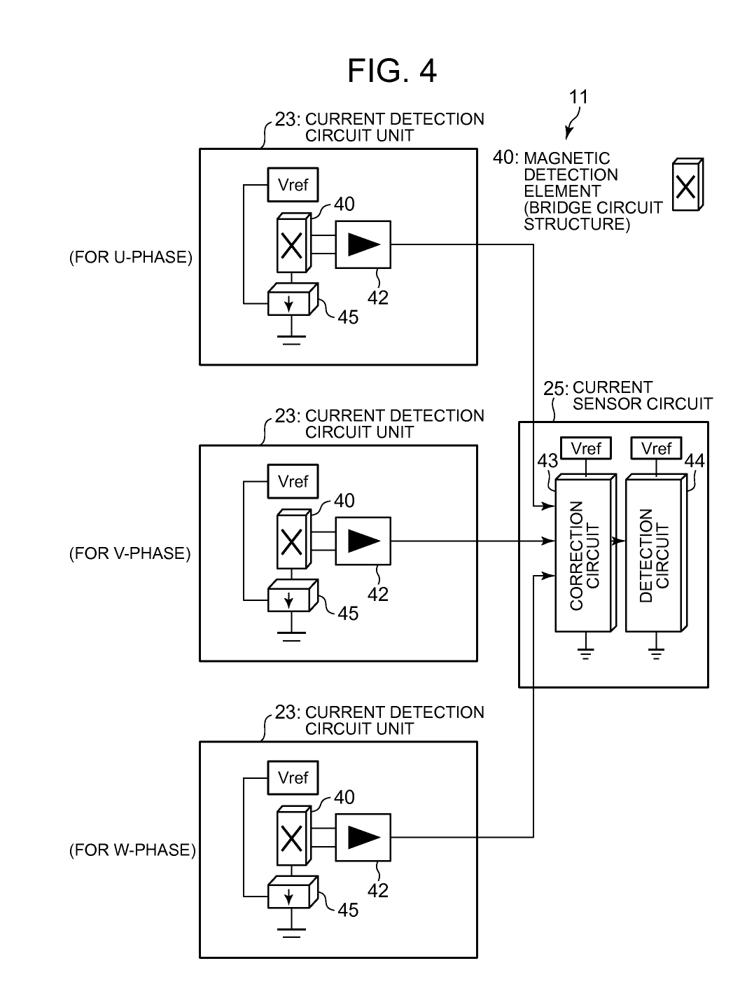

The current sensor circuit 25 generates the detection signals of the current values of the respective bus bars 15 on the basis of the outputs of the respective magnetic detection elements 40 provided in association with the bus bars 15 of the respective phases, and outputs the respective detection signals to the control IC 7. The current sensor circuit 25 has a correction circuit 43 and a detection circuit 44 (see FIG. 4) as described later.

In this embodiment, as shown in FIG. 1, one current sensor circuit 25 is commonly used for the respective magnetic detection elements 40, mounted on the mount face 9A of the control circuit board 9 and connected to the control IC 7 through wires printed on the mount face 9A. The current sensor circuit 25 may be individually provided to each magnetic detection element 40.

As described above, in the three-phase inverter circuit module 1, the current detection modules 11 are mounted on the control circuit board 9 on which the control IC 7 is mounted, the pass portions 29 through which the bus bars 15 are passed to the obverse and reverse sides are provided to the control circuit board 9, and the bus bars 15 passing through the pass portions 29 are mounted so as to be surrounded by the magnetic cores 21 provided to the current detection circuit modules 11. Therefore, even before the module is fabricated, the current detection sensitivity of the current detection circuit module 11 can be corrected with the control circuit board 9 set alone.

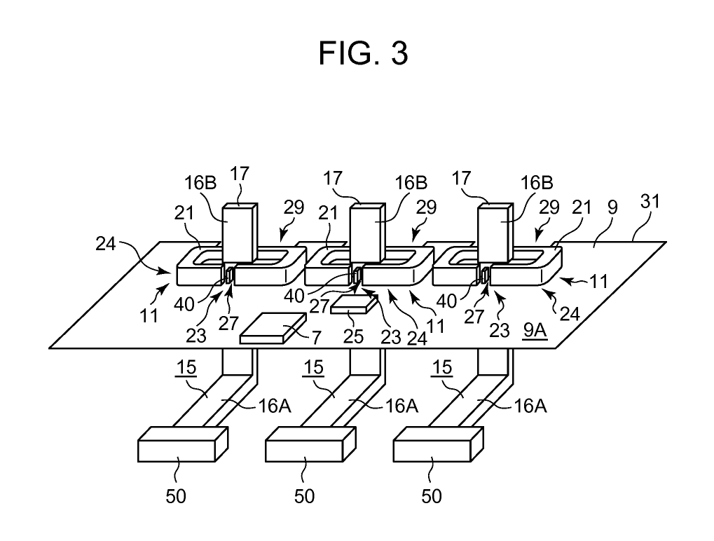

With respect to the correction procedure of the current detection sensitivity, the control IC 7 and the current detection circuit modules 11 (the magnetic cores 21, the magnetic detection elements 40 and the current sensor circuit 25) are first mounted on the control circuit board 9. Thereafter, as shown in FIG. 3, reference current sources 50 are connected to the end portions of the bus bars 15 while the bus bars 15 are passed through the pass portions 29 of the control circuit board 9 vertically to the mount face 9A of the control circuit board 9 so as to be arranged vertically to the magnetic cores 21. The reference current sources 50 are current sources for outputting reference test current. When this current flows through the bus bar 15, the magnetic flux corresponding to the test current occurs in the gap 27 of the magnetic core 21 of the current detection circuit module 11, and the signal corresponding to the density of the magnetic flux is output from the magnetic detection element 40 to the current sensor circuit 25.

The current detection sensitivity is corrected by correcting the output from the magnetic detection element 40 under the state that the test current is made to flow through the bus bar 15, and correction values of various kinds of parameters obtained through this correction are recorded in a correction circuit 43 of the current sensor circuit 25. The correction values may be stored in a storage element which is separately provided to the control circuit board 9.

Subsequently, the magnetic detection element 40 and the current sensor circuit 25 described above will be described in detail.

FIG. 4 is a circuit diagram showing the constructions of the magnetic detection element 40 and the current sensor circuit 25.

As shown in FIG. 4, the magnetic detection element 40 constitutes the current detection circuit unit 23 together with a stabilized power supply 45 for driving the magnetic detection element 40 and a differential amplifier 42 for amplifying the output of the magnetic detection element 40. The current detection device 24 (FIG. 1) mounted on the control circuit board 9 is configured to have the current detection circuit unit 23 and the magnetic core 21.

The stabilized power supply 45 contains any one of a stabilized voltage source and a stabilized current source, and drives the magnetic detection element 40 as the hall element so that the linearity of the output characteristic to the magnetic flux density is obtained.

In FIG. 4, Vref is a reference voltage of a predetermined voltage (for example, 5V). The differential amplifier 42 and the stabilized power supply 45 are omitted from the illustrations of the other figures such as FIG. 1, etc.

Here, an element for correcting the sensitivity of the magnetic detection element 40 is normally contained in each current detection circuit unit 23 in prior arts. It is general to change the resistance value of a resistance element (not shown) connected to a non-inversion input of the differential amplifier 42 for the correction of sensitivity, and an element such as a trimming resistor or the like which can be arbitrarily adjusted in resistance value is broadly used as the resistance element. However, in this construction, it is necessary to correct the resistance element of each current detection circuit unit 23, and thus the correction work is complicated. Furthermore, the sensitivity correction based on the trimming resistor is an analog type correction for changing the resistance value by a process such as physical processing or the like to correct the sensitivity, and thus the correction precision thereof is limited. In addition, it is impossible to perform re-setting.

Therefore, this embodiments enables the sensitivity correction which is not performed in an analog style, but performed in a digital style. As compared with the correction based on the analog style, the correction based on the digital style has advantages that it does not require any special facilities for writing a correction value, the correction value is rewritable at any time and approach to the optimum point based on feedback control (specification of a correction value providing the optimum point) can be performed. However, when the resistance element of the current detection circuit unit 23 is merely replaced by a resistance-value variable digital device such as a digital potentiometer or the like to implement the sensitivity correction based on the digital style, a non-volatile memory, a digital control circuit, etc. to store the correction value are required, so that the circuit scale increases and a power source and a control circuit for driving the non-volatile memory and the digital control circuit are required. Therefore, there are disadvantages that the number of parts increases and the cost also increases.

Therefore, according to this embodiment, as shown in FIG. 4, each current detection circuit unit 23 is not incorporated with any part for correcting the sensitivity of the magnetic detection element 40, but an integrated correction circuit 43 for correcting the sensitivity of the magnetic detection element 40 of each current detection circuit unit 23 is provided at the rear stage of each current detection circuit unit 23. Furthermore, the correction circuit 43 is integrated and constructed as a current sensor circuit 25 together with a detection circuit 44 for generating a detection signal of a current value on the basis of a signal of the current detection circuit unit 23 and outputting the detection signal, so that the number of parts can be greatly reduced.

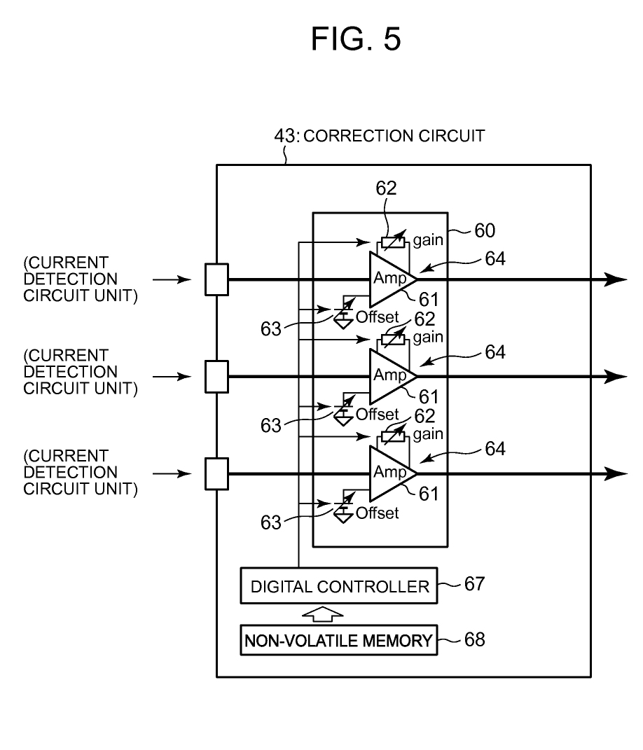

FIG. 5 is a circuit diagram showing an example of the construction of the correction circuit 43 for correcting the sensitivity of the magnetic detection element 40 in the digital style.

The correction circuit 43 of this embodiment performs gain correction and off-set correction as correction for the signal output from each current detection circuit unit 23, and has an amplification unit 60, a digital controller 67 and a non-volatile memory 68 as shown in FIG. 5.

The amplification unit 60 has a correction unit 64 which is provided every input of each current detection circuit unit 23 and has an amplifier 61 for amplifying the signal of the current detection circuit unit 23, a digital potentiometer 62 as a variable resistor in which a resistance value for adjusting the gain of the amplifier 61 is digitally settable, and a DC voltage variable power supply 63 in which a DC voltage for adjusting the offset of the signal of the current detection circuit unit 23 is digitally settable. The gain correction is performed on the basis of the resistance value of the digital potentiometer 62, and the offset correction is performed on the basis of the voltage of the DC voltage variable power supply 63.

The non-volatile memory 68 stores the resistance values of the respective digital potentiometers 62 and the voltage values of the respective DC voltage variable power supplies 63 as the correction values of the sensitivity of the magnetic detection elements 40. These correction values are written into the non-volatile memory 68 by a sensitivity correction work of the magnetic detection elements 40 which is performed in a shipping inspection step or the like.

The digital controller 67 is configured to contain a microcomputer, for example, and outputs the correction values of the non-volatile memory 68 to the digital potentiometer 62 and the DC voltage variable power supply 63 to set the correction values as the resistance value of the digital potentiometer 62 and the DC voltage of the DC voltage variable power supply 63, thereby performing the gain correction and the offset correction.

In the correction circuit 43, the respective devices such as the amplification unit 60, the digital controller 67 and the non-volatile memory 68 are constructed as a monolithic device, and they are integrated as one IC at the rear stage of each current detection circuit unit 23, whereby the number of parts to be mounted and the cost are be reduced while the correction based on the digital style is performed.

Furthermore, in this embodiment, the correction circuit 43 is integrated with the detection circuit 44, and they are configured as one current sensor circuit 25. Therefore, the number of parts to be mounted and the cost are more greatly reduced.

As shown in FIG. 4, the current detection circuit units 23 are constructed by discrete parts, and the correction circuit 43 for correcting the sensitivity of each magnetic detection element 40 in the digital style can be integrated as one body. Therefore, as compared with the construction that each current detection circuit unit 23 is configured to contain an element for correcting the sensitivity of the magnetic detection element 40, the device can be greatly miniaturized and the cost can be greatly reduced.

The correction circuit 43 may be configured to contain a temperature sensor or connected to an external temperature detection element so that temperature correction is performed on the basis of temperature information detected by the temperature sensor or the external temperature detection element.

The correction circuit 43 and the detection circuit may be integrated separately from each other, and the non-volatile memory 68 may be provided separately from the correction circuit 43.

As described above, according to this embodiment, the magnetic core 21 and the magnetic detection element 40 are mounted together on the control circuit board 9 on which the control IC 7 and the current sensor circuit 25 containing the detection circuit 44 are mounted, and the pass portions 29 in which the bus bars 15 as the current conducting wires of a detection target are passed are provided to the control circuit board 9. Therefore, a conductor in which current for correcting sensitivity is made to flow is passed through the pass portion in place of the bus bar 15 of the power module 5, whereby the sensitivity of the magnetic detection element 40 can be corrected by using only the control circuit board 9 without fabricating the power module 5. Accordingly, this embodiment can simplify the shipping inspection step, suppress the work-in-process loss and contribute to flexible production.

Furthermore, the magnetic core 21 is mounted on the control circuit board 9, whereby the resistance to the mechanical impact can be enhanced.

Particularly, according to this embodiment, the magnetic core 21 is disposed so as to be fit within the mount face 9A of the control circuit board 9, whereby the contact area between the magnetic core 21 and the control circuit board 9 becomes maximum and thus the resistance to the mechanical impact can be enhanced to the maximum level.

Furthermore, the magnetic cores 21 are grounded to the control circuit board 9, whereby the capacitance between the magnetic core 2 and the control circuit board 9 and the capacitance between the magnetic core 21 and the magnetic detection element 40 can be reduced. Accordingly, the effect of the electrostatic induction noise caused by current flowing through the bus bar 15 can be reduced.

According to this embodiment, the magnetic core 21 and the magnetic detection element 40 are provided for each of the plural bus bars 15 extending from the power module 5, and the correction circuit 43 for correcting the output of each magnetic detection element 40 and outputting the corrected output to the detection circuit 4 is mounted on the control circuit board 9. Accordingly, circuits which respectively correct the plural magnetic detection elements 40 are integrated into one correction circuit 43, and thus the number of parts to be mounted is greatly reduced.

Furthermore, according to this embodiment, the correction circuit 43 is configured to have the amplifier 61 for amplifying the output of each of the magnetic detection elements 40 and outputting the amplified output to the detection circuit 44, the digital potentiometer 62 as a variable resistor in which the resistance value for adjusting the gain of the amplifier 61 every magnetic detection element 40 is digitally settable, the DC voltage variable power supply 63 in which a DC voltage for adjusting the offset of the output of each of the magnetic detection element 40 is digitally settable, and a digital controller 67 as control means for setting the adjustment values of gain and offset to the digital potentiometer 62 and the DC voltage variable power supply 63 every magnetic detection element 40.

Accordingly, the sensitivity of each magnetic detection element 40 can be digitally corrected, and thus the sensitivity can be accurately set and also re-settable as compared with the correction based on the analog style which changes the resistance value by using a trimming resistor or the like to correct the gain, for example. Furthermore, the amplifier 61, the digital potentiometer 62, the DC voltage variable power supply 63 and the digital controller 67 can be constructed as a monolithic device, and integrated into one circuit. Therefore, the number of parts to be mounted and the cost can be reduced while the correction based on the digital style can be performed.

Furthermore, according to this embodiment, the digital portion can be integrated, so that the number of parts can be reduced and the cost of the semiconductor itself can be reduced.

The foregoing embodiment is merely an example of the present invention, and any modification and any application may be made without departing from the subject matter of the present invention.

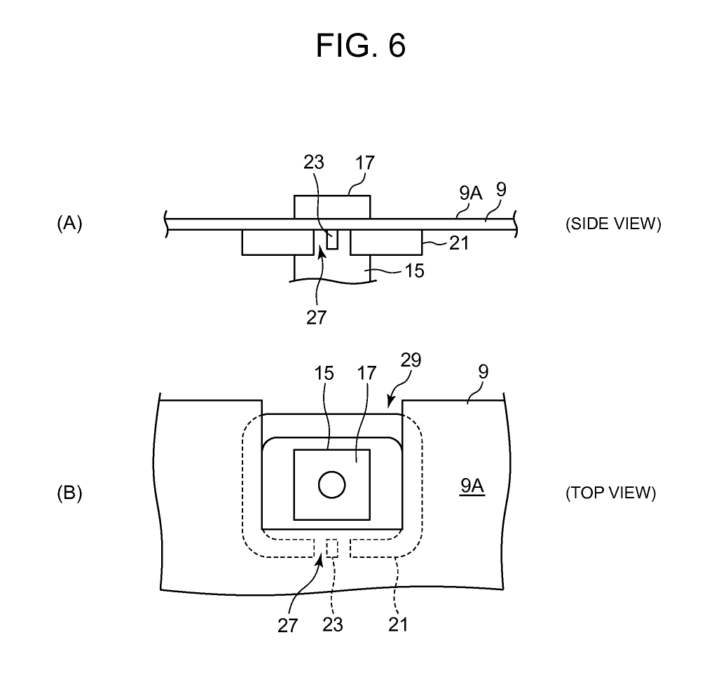

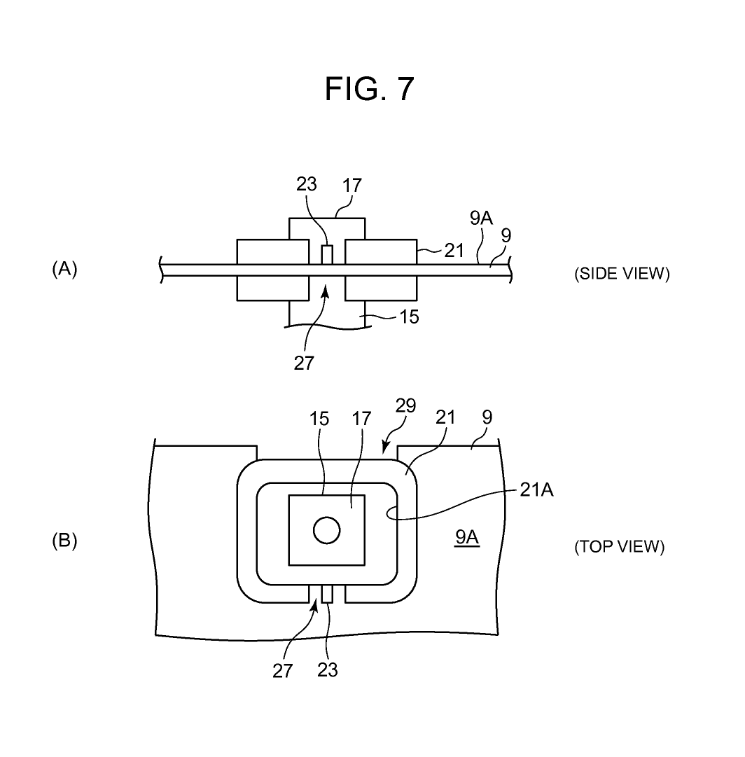

For example, with respect to the arrangement of the magnetic cores 21 on the control circuit board 9, any arrangement style may be adopted insofar as the inner peripheral surface 21A of the magnetic core 21 is vertical to the mount face 9A of the control circuit board 9. That is, in place of the arrangement that the magnetic core 21 is arranged on the upper surface (the mount face 9A on which the control IC 7 is mounted) of the control circuit board 9, the magnetic core 21 may be arranged on the lower surface of the control circuit board 9 (the reverse-side surface of the mount face 9A on which the control IC 7 is mounted) as shown in FIG. 6(A) and FIG. 6(B), or the magnetic core 21 may be arranged so as to penetrate through the control circuit board 9 to the obverse and reverse sides as shown in FIG. 7(A) and FIG. 7(B). According to the construction of FIG. 7, the protrusion of the magnetic core 21 from the surface of the control circuit board 9 can be suppressed, and the rigidity of the control circuit board 9 can be enhanced by the magnetic core 21.

In the construction shown in FIG. 6 and FIG. 7, the control circuit board 9 may be configured as a double-side mount type board so that electrical circuits are mounted on both the obverse and reverse surfaces thereof.

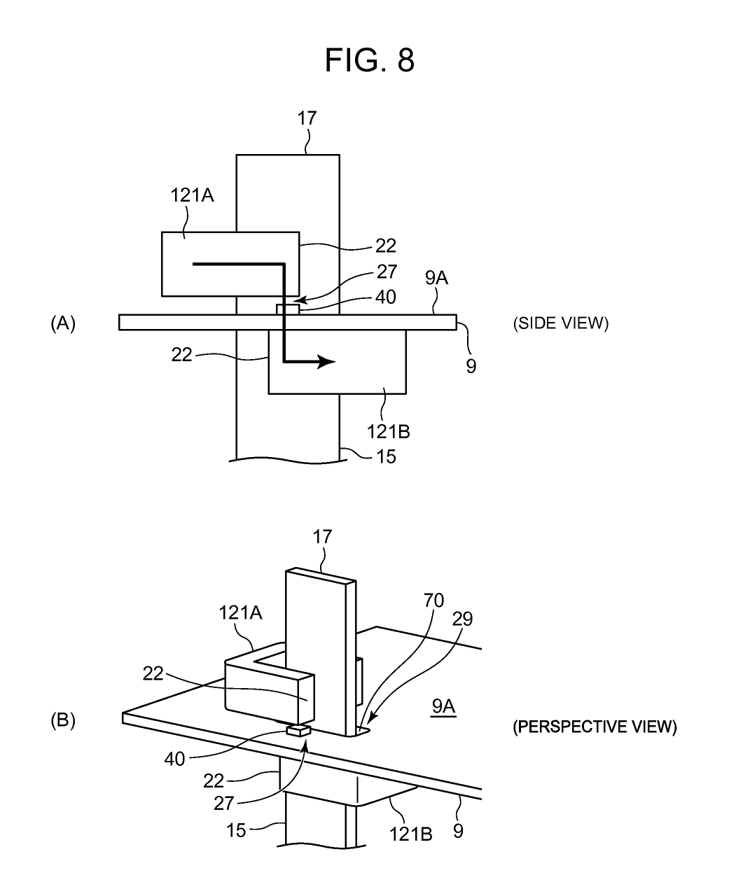

Furthermore, as shown in FIG. 8(A) and FIG. 8(B), the magnetic core 21 may be divided into an upper magnetic core 121A and a lower magnetic core 121B at the left and right sides which are shaped to be substantially U-shaped in plan view. The upper magnetic core 121A and the lower magnetic core 121B are arranged at the upper and lower sides of the control circuit board 9 so as to sandwich the control circuit board 9 therebetween so that the open end portions 22 thereof are overlapped with each other, and the magnetic detection element 40 is disposed between the respective open end portions 22. However, in this construction, in order to enhance the resistance to impact, the pass portion 29 for the bus bar 15 is not formed by cutting out the edge portion 31 of the control circuit board 9, but a pass hole 70 is formed at only a portion through which the bus bar 15 penetrates is formed in the surface of the control circuit board 9, thereby constructing the pass portion 29.

According to the construction shown in FIGS. 6 and 8, the magnetic core 21 is wholly or partially arranged at the reverse surface side, and the obverse and reverse surfaces of the control circuit board 9 can be efficiently used. Furthermore, the degree of freedom of the layout on the mount face 9A side (both the obverse and reverse surfaces in case of the double-side mount type control circuit board 9) can be enhanced.

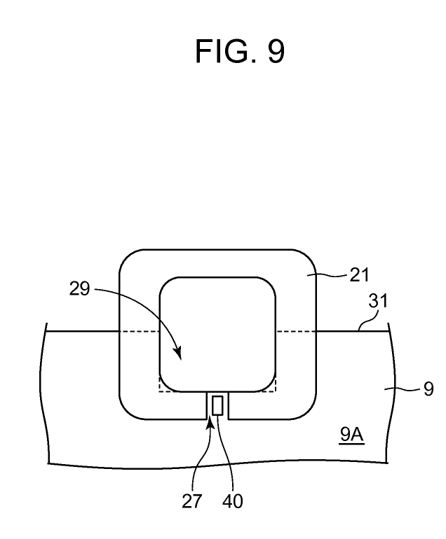

It is unnecessary that the magnetic core 21 is disposed to be fit within the mount face 9A of the control circuit board 9, and a part of the magnetic core 21 may protrude from the edge portion 31 of the control circuit board 9 as shown in FIG. 9.

For example, in place of providing the pass portion 29 by cutting out the edge portion 31 of the control circuit board 9, a through-hole 71 through which the bus bar 15 penetrates to the obverse and reverse sides may be formed in the mount face 9A of the control circuit board 9, and the magnetic core 21 may be mounted so as to surround the through-hole 71.

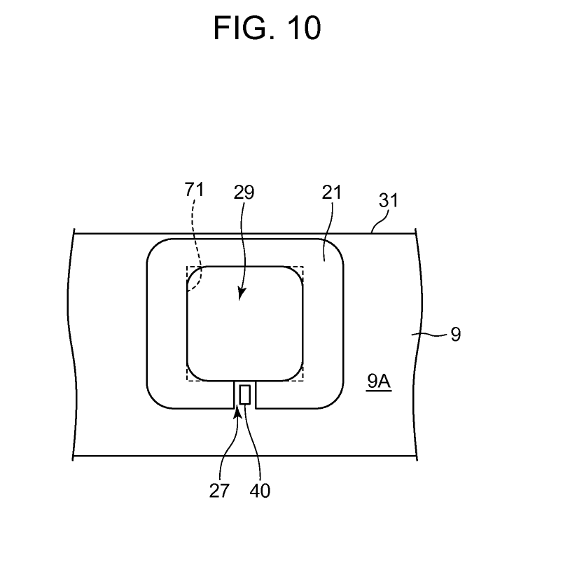

As shown in FIG. 10 and FIGS. 1 to 3, the magnetic core 21 is arranged so as to be fit within the mount face 9A of the control circuit board 9, whereby the contact area between the magnetic core 21 and the control circuit board 9 can be increased and the resistance to the mechanical impact can be enhanced.

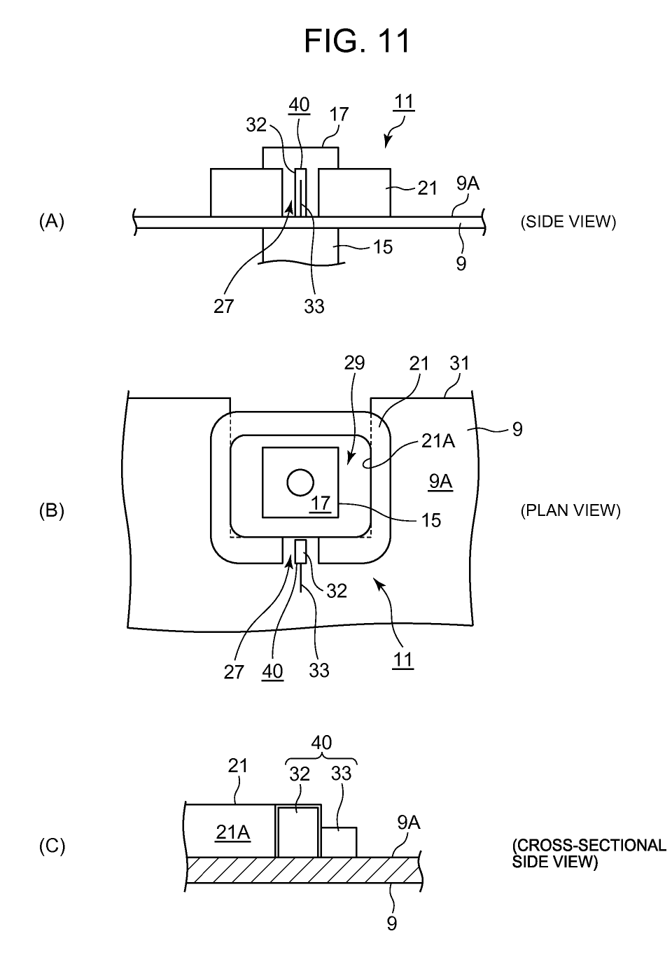

Furthermore, for example, when the magnetic detection element 40 is mounted in the gap 27 of the magnetic core 21 as shown in FIGS. 11(A) to 11(C), the terminal portion 33 of the magnetic detection element 40 may be secured at the outside of the gap 27 of the magnetic core 21 out of the mount face 9A of the control circuit board 9, and the terminal portion 33 is bent so that IC portion 31 comes to the center of the gap 27.

Furthermore, for example, the current detection circuit unit 23 is configured to contain the magnetic detection element 40, the stabilized power supply 45 and the differential amplifier 42, and it is provided for each of U-phase, V-phase and W-phase. However, the present invention is not limited to this embodiment, and other analog circuits excluding the magnetic detection element 40 (the stabilized power supply 45 and the differential amplifier 42) may be integrated commonly to the respective magnetic detection elements 40.

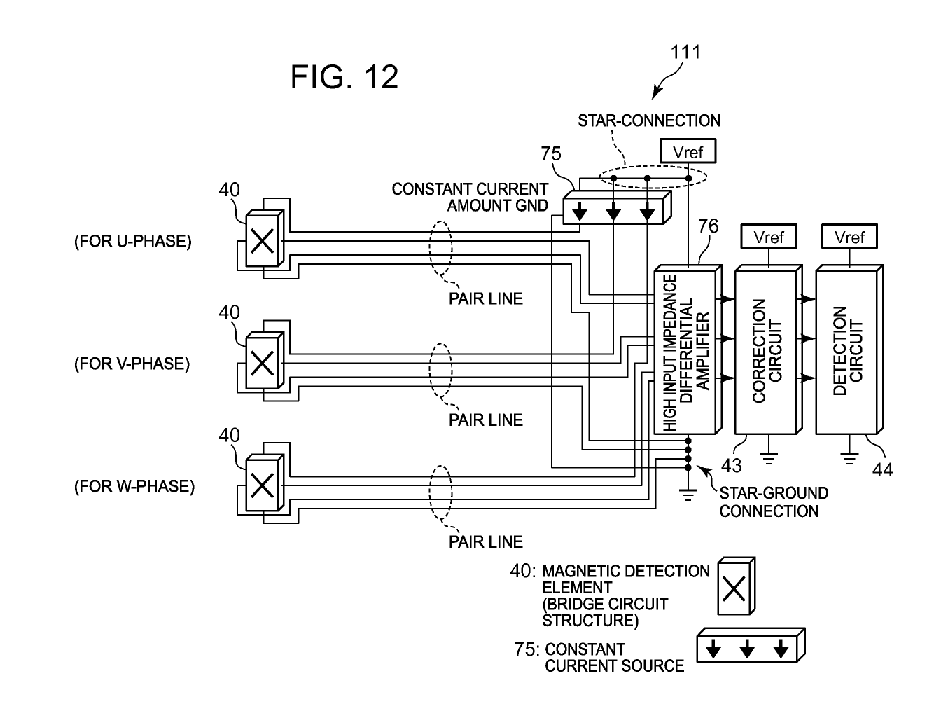

That is, in the current detection circuit module 111 according to this invention, as shown in FIG. 12, a constant current source 75 as an embodiment of a stabilized power supply for supplying constant current to each of the magnetic detection elements 40 and a high input impedance differential amplifier 76 for amplifying and outputting an output signal of each of the magnetic detection element 40 are provided at the front stage of the correction circuit 43, and they are connected to a reference voltage Vref in a star-connection style.

Accordingly, the constant current source 75 and the high input impedance differential amplifier 76 are integrated, and the number of parts to be mounted and the cost can be reduced. The high input impedance differential amplifier 76 and the correction circuit 43 may be integrated with each other, and additionally integrated with the detection circuit 44.

As shown in FIG. 12, the grounding positions of the respective magnetic detection elements 40, the constant current source 75 and the high input impedance differential amplifier 76 are subjected to star-ground connection, and also the input impedance of the high input impedance differential amplifier 76 as the analog circuit can be increased, thereby eliminating a ground loop causing malfunction.

The wires for connecting the respective magnetic detection elements 40 to the constant current source 75, the high input impedance differential amplifier 76 and the ground are designed as pair lines, whereby noise can be reduced. Furthermore, noise may be removed by arranging a low pass filter (Low Pass Filter) at the front stage of the high input impedance differential amplifier 76.

Furthermore, the means for correcting the current detection sensitivity of the magnetic detection element 40 is not limited to hardware type correction for performing the gain correction and the offset correction by using hardware (the digital potentiometer 62 and the DC voltage variable power supply 63), and it may be software type correction.

That is, when the sensitivity of the magnetic detection element 40 is corrected by using the software type correction, in place of the correction circuit 43, a circuit for adding correction coefficients of the magnetic detection elements 40 (predetermined values determined by the current detection sensitivity correction in a manufacturing shipping step or the like) to values output from an A/D converter equipped to the detection circuit 44 (that is, the current values of the respective phases) to thereby correct the values and outputs the corrected values as the current values is provided at the rear stage of the detection circuit 44 or together with the detection circuit 44.

The correction based on the hardware style is more excellent in responsibility and followability as compared with the correction based on the software style. Therefore, when they are required, it is desirable to use the correction based on the hardware style.

For example, in the construction of the current detection circuit unit 23 shown in FIG. 4, the magnetic core 21 may be provided with a circuit for feeding back the output of the differential amplifier 42, whereby the current detection circuit unit 23 is configured in a closed loop structure.

Furthermore, the three-phase inverter circuit may be exemplified as the power module. However, the present invention is not limited to this style, and the current detection circuit module according to the present invention may be applied to current detection of any power module in which relatively large current flows.

### DESCRIPTION OF REFERENCE NUMERALS

1 three-phase inverter circuit module
3 three-phase rotating electric machine
5 power module
9 control circuit board
9A mount face
7 control IC (control circuit)
11, 111 current detection circuit module
15 bus bar (current conducting wire)
21 magnetic core
21A inner peripheral surface
23 current detection circuit unit
25 current sensor circuit
27 gap
29 pass portion
32 IC portion
33 terminal portion
40 magnetic detection element
43 correction circuit
44 detection circuit
45 stabilized power supply
61 amplifier
62 digital potentiometer (variable resistor)
63 DC voltage variable power supply
64 correction unit
67 digital controller (control means)
68 non-volatile memory
71 through-hole
75 constant current source
76 high input impedance differential amplifier (amplifier)

1. A current detection circuit module having a control circuit board on which a control circuit for controlling a power module is mounted, a magnetic core that surrounds a current conducting wire extending from the power module and has a gap at a part thereof, a magnetic detection element disposed in the gap, and a detection circuit for outputting a detection signal of a current value flowing in the current conducting wire to the control circuit in accordance with an output of the magnetic detection element, the detection circuit being mounted on the control circuit board, wherein the control circuit board is provided with a pass portion based on a cut-out or through-hole to dispose the current conducting wire vertically to the surface of the board, the magnetic core is provided to the control circuit board so as to surround the current conducting wire through the pass portion, and the magnetic detection element is provided to the control circuit board so as to be located in the gap of the magnetic core.

2. The current detection circuit module according to claim 1, wherein the magnetic core is disposed so as to be fit within the surface of the control circuit board.

3. The current detection circuit module according to claim 1, wherein the magnetic core and the magnetic detection element are provided for each of plural current conducting wires extending from the power module, and a correction circuit for correcting an output of each of the magnetic detection elements and outputting the corrected output to the detection circuit or correcting a detection signal of each magnetic detection element output from the detection circuit and outputting the corrected detection signal is mounted on the control circuit board.

4. The current detection circuit module according to claim 1, wherein the magnetic core is disposed on the surface of the control circuit board.

5. The current detection circuit module according to claim 1, wherein the magnetic core is provided so as to penetrate through the control circuit board to the obverse and reverse surfaces of the control circuit board.

6. The current detection circuit module according to claim 1, wherein the magnetic core is divided into a first magnetic core and a second magnetic core that are configured to be substantially U-shaped in plan view and arranged so as to sandwich the control circuit board from upper and lower sides so that open end portions of the first and second magnetic cores are overlapped with each other in plan view, and the magnetic detection element is provided between the open end portions of the first and second magnetic cores.

7. The current detection circuit module according to claim 1, wherein the magnetic core is electrically grounded to the control circuit board.
